(19) United States
(12) Patent Application Publication
(10) Pub. No.: US 2004/0051101 A1
(43) Pub. Date: Mar. 18, 2004

(54) Thin film transistor device, method of manufacturing the same, and thin film transistor substrate and display having the same

(75) Inventors: Kazushige Hotta, Kawasaki (JP); Yoshio Kurosawa, Kawasaki (JP)

Correspondence Address: Patrick G. Burns, Esq., GREER, BURNS & CRAIN, LTD., Suite 2500, 300 South Wacker Dr., Chicago, IL, 60606, US

(73) Assignee: FUJITSU DISPLAY TECHNOLOGIES CORPORATION

(21) Appl. No.: 10/612,385

(22) Filed: Jul. 2, 2003

(30) Foreign Application Priority Data
Jul. 5, 2002 (JP) 2002-197881

(51) Int. Cl. H01L 21/00

(52) U.S. Cl. 257/72; 438/48

(57) ABSTRACT

LDD regions can be properly formed even when a gate insulation film is thin, and an impurity can be properly activated. After forming a gate electrode, an n-type impurity is implanted in a high density using a resist mask for etching the gate insulation film as a mask. A SiO₂ film is formed as a first interlayer insulation film, and activation is thereafter performed using a laser. By implanting the impurity with the resist mask for etching left in place, the problem of excessive implantation of the n-type impurity in the LDD regions can be avoided without adding a photolithographic process even when the gate insulation film is thin. The reflectivity of the high density impurity-implanted regions that are source and drain regions against laser light and the reflectivity of the LDD regions can be made substantially equal to each other by changing the thickness of the SiO₂ film that is the first layer insulation film depending on the thickness of the gate insulation film, which allows those regions to be activated simultaneously and sufficiently.

### BACKGROUND OF THE INVENTION

1. Field of the Invention

The present invention relates to thin film transistor (TFT) devices, a thin film transistor substrate on which such devices are integrated, and a method of manufacturing the same and, more particularly, to a TFT substrate on which TFTs utilizing polysilicon (p-Si) semiconductor layers are integrated, a method of manufacturing the same, and a display (a liquid crystal display (LCD), in particular).

2. Description of the Related Art

Liquid crystal displays are used in various fields as display sections of PDAs (Personal Digital Assistants) and notebook PCs (personal computers) and video camera finders thanking to their lightweights, low profiles and low power consumption. In order to achieve cost reduction, LCDs integrated with peripheral circuits are recently spreading in which peripheral circuits including TFTs are formed outside a display area at the same time when pixel driving TFTs in the display are formed. An LCD integral with peripheral circuits is manufactured using a low temperature polysilicon manufacturing process, for example. Polysilicon TFTs whose channel regions formed of polysilicon are used as pixel driving TFTs and peripheral circuit TFTS. In order to reduce display defects attributable to a leak current, a polysilicon TFT for driving a pixel must have a low density impurity-doped region (LDD: lightly doped drain) provided between a channel region and each of source and drain regions. On the contrary, TFTs of a peripheral circuit section are formed with no LDD region because it is less susceptible to a leak current and it must operate at a high speed.

In order to achieve low power consumption, TFTs of a peripheral circuit is normally configured as a CMOS circuit. To form a CMOS circuit, it is required to form an n-channel TFT having a channel region of the negative conductivity type and a p-channel TFT having a channel region of the positive conductivity type on the same substrate. For this reason, the formation of a CMOS circuit involves a greater number of manufacturing steps than the manufacture of TFTs of a single conductivity type.

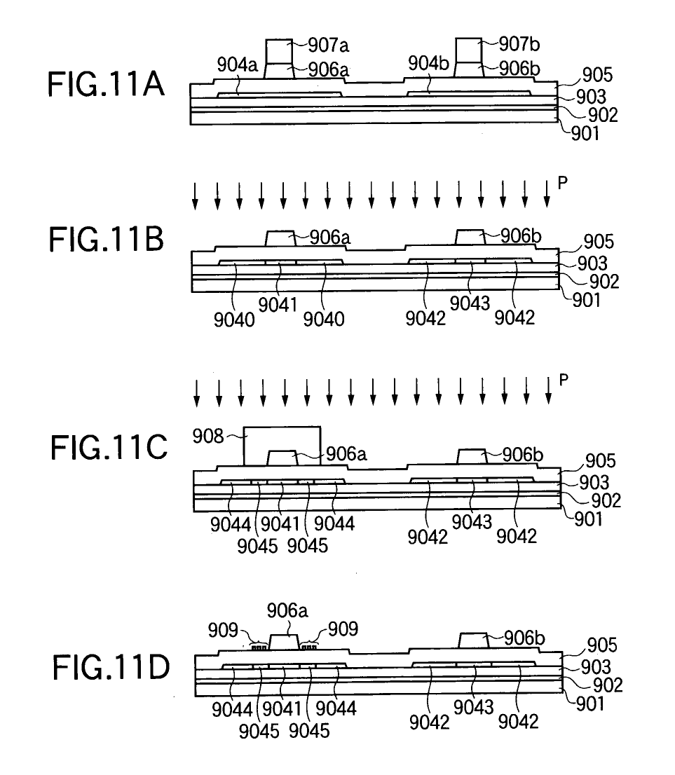

A description will now be made with reference to FIGS. 11A to 11D on a method according to the related art in which a mixture of a TFT having LDD regions and a TFT having no LDD region is formed on the same substrate. FIGS. 11A to 11D are sectional views taken in processes showing a first example a method of manufacturing a TFT substrate according to the related art. In FIGS. 11A to 11D, a region where an n-channel TFT having LDD regions is to be formed is shown on the left side of the figures and a region where an n-channel TFT having no LDD region is to be formed is shown on the right side of the same.

First, as shown in FIG. 11A, an underlying SiN film 902 and a SiO₂ film 903 are formed in the order listed throughout a top surface of a transparent insulated substrate 901 made of glass or the like using a plasma CVD apparatus. Subsequently, an amorphous silicon (a-Si) film is formed throughout a top surface of the SiO₂ film 903. The amorphous silicon is then crystallized using an excimer laser to form a polysilicon film 904. A resist is then applied to the entire surface and patterned, and dry etching is performed with a fluorine type gas using the patterned resist layer as a mask to form polysilicon films 904a and 904b in the form of islands.

The resist layer is then peeled off, and a SiO₂ film is formed on the polysilicon films 904a and 904b throughout the substrate using a plasma CVD apparatus to provide an insulation film 905 (that is referred to as “gate insulation film” when located under a gate electrode). An Al—Nd film 906 to become gate electrodes is then formed throughout a top surface of the gate insulation film 905 using a sputtering apparatus. Next, a resist is applied and patterned to form resist masks 907a and 907b in the form of gate electrodes on the Al—Nd film 906. The Al—Nd film 906 is etched with an Al etcher using the resist masks to form gate electrodes 906a and 906b. The resist masks 907a and 907b are thereafter peeled off.

Next, as shown in FIG. 11B, first doping is performed by implanting an n-type impurity such as phosphorous (P) ions through the insulation film 905 with an ion doping apparatus using the gate electrodes 906a and 906b as masks. The density of the impurity implanted during the first doping is relatively low. Thus, the n-type impurity is implanted in parts 9040 to become LDD regions and source and drain regions of the polysilicon film 904a in the region where an n-channel TFT having LDDs is to be formed, and the impurity is not implanted in a part 9041 to become a channel region. The n-type impurity is implanted in parts 9042 to become source and drain regions of the polysilicon film 904b where an n-channel TFT having no LDD is to be formed, and the impurity is not implanted in a part 9043 to become a channel region.

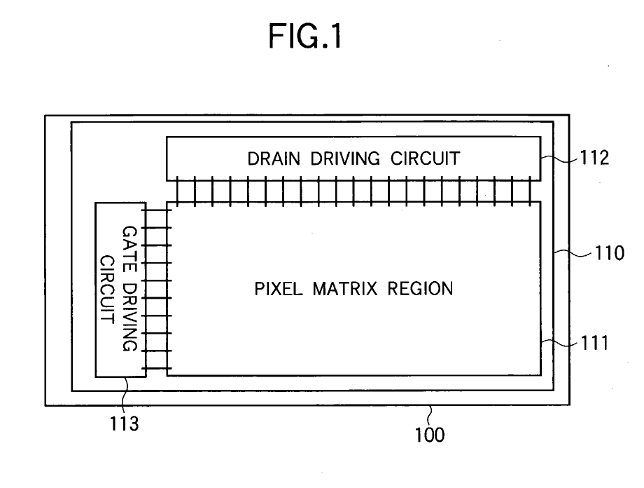

Next, as shown in FIG. 1C, a resist layer 908 is formed such that it covers the parts to become LDD regions of then-channel TFT to be formed with LDDs and the gate electrode 906a. Second doping is performed by implanting an n-type impurity such as P ions through the insulation film 905 with an ion doping apparatus using the resist layer 908 as a mask. The impurity density during the second doping is higher than that of the first doping. Thus, the polysilicon film 904a in the region to form an n-channel TFT having LDDs is formed with source and drain regions 9044 in which the n-type impurity is implanted in a relatively high density, LDD regions 9045 in which the n-type impurity is implanted in a density lower than that in the source and drain regions 9044 and a channel region 9041 in which then-type impurity is not implanted at all. On the contrary, the polysilicon film 904b in the region to form an n-channel TFT having no LDD is formed with source and drain regions 9042 in which the n-type impurity is implanted in a relatively high density and a channel region 9043 in which the n-type impurity is not implanted at all. The first and second cycles of doping take a long time for implantation because the impurity is implanted through the insulation film 905.

Next, as shown in FIG. 11D, the resist layer 908 is removed through ashing, but it is difficult to remove the resist layer 908 completely because it is altered as a result of the second doping that takes a long time. As a result, a residual resist 909 remains after the ashing.

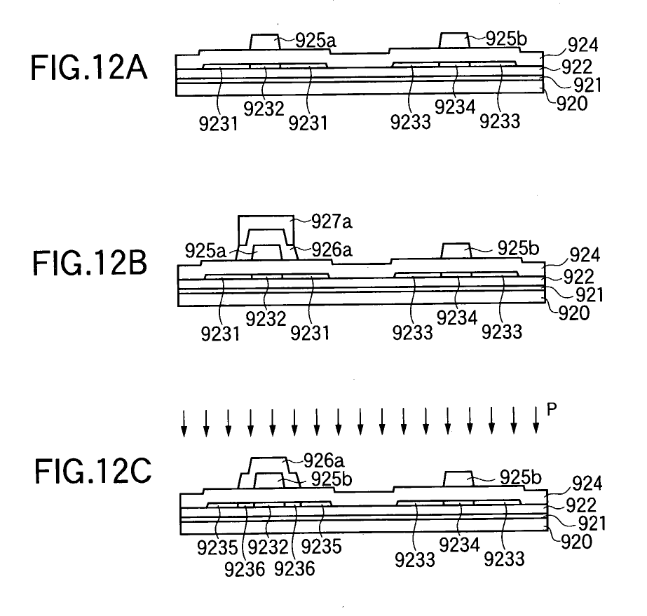

JP-A-9-246558 has disclosed a method of solving the problems of a prolonged time for impurity implantation and a residual resist. The method according to the related art disclosed in the same publication will now be described with reference to sectional views taken in manufacturing processes as shown in FIGS. 12A to 12C. FIGS. 12A to 12C show a region where an n-channel TFT having LDD regions is to be formed on the left side and show a region where an n-channel TFT having no LDD region is to be formed on the right side.

First, as shown in FIG. 12A, an underlying SiN film 921 and an SiO₂ film 922 are formed in the order listed throughout a top surface of a transparent insulated substrate 920 made of glass or the like using a plasma CVD apparatus. An amorphous silicon film is then formed throughout a top surface of the SiO₂ film 922. The amorphous silicon is then crystallized using an excimer laser to form a polysilicon film 923. Thereafter, a resist is applied to the entire surface and patterned, and dry etching is performed with a fluorine type gas using the patterned resist layer as a mask to form polysilicon films in the form of islands.

Next, the resist layer is peeled off, and a SiO₂ film is formed on the polysilicon films throughout the substrate using a plasma CVD apparatus to form an insulation film (that is referred to as “gate insulation film” when located under a gate electrode) 924. Then, an Al—Nd film 925 to become gate electrodes is formed throughout a top surface of the insulation film 924 using a sputtering apparatus. A resist is then applied and patterned to form resist masks in the form of gate electrodes on the Al—Nd film 925. The Al—Nd film is etched with an Al etcher using the resist masks to form gate electrodes 925a and 925b. The resist masks are thereafter peeled off.

Next, first doping is performed by implanting an n-type impurity such as P ions through the insulation film 924 with an ion doping apparatus using the gate electrodes 925a and 925b as masks. The density of the impurity implanted during the first doping is relatively low. Thus, then-type impurity is implanted in parts 9231 to become LDD regions and source and drain regions of the polysilicon film in the region where an n-channel TFT having LDDs is to be formed, and the impurity is not implanted in a part 9232 to become a channel region. The n-type impurity is implanted in parts 9233 to become source and drain regions of the polysilicon film where an n-channel TFT having no LDD is to be formed, and the impurity is not implanted in a part 9234 to become a channel region.

Next, as shown in FIG. 12B, an insulation film 926 of a material (e.g., SiN) different from that of the insulation film 924 made of SiO₂ or the like is formed throughout the substrate. Then, a resist layer 927a is formed such that it covers the gate electrode 925a of the n-channel TFT to be formed with LDDs and the parts of the polysilicon film to become the LDD regions. The insulation film 926 is etched using the resist layer 927a as a mask to form an insulation film 926a such that it covers the gate electrode 925a of the n-channel TFT to be formed with LDDs and the parts of the polysilicon film to become the LDD regions. The insulation film 926 is removed completely in the region where an n-channel TFT having no LDD is to be formed. The resist mask 927a is thereafter peeled off.

Next, as shown in FIG. 12C, second doping is performed by implanting an n-type impurity such as P ions through the insulation film 924 with an ion doping apparatus using the insulation film 926a as a mask. The impurity density during the second doping is higher than that of the first doping. Thus, the polysilicon film in the region to form the n-channel TFT having LDDs is formed with source and drain regions 9235 in which the n-type impurity is implanted in a relatively high density, LDD regions 9236 in which the n-type impurity is implanted in a density lower than that in the source and drain regions 9235, and a channel region 9232 in which the n-type impurity is not implanted at all. The polysilicon film in the region to form an n-channel TFT having no LDD is formed with source and drain regions 9233 in which the n-type impurity is implanted in a relatively high density and a channel region 9234 in which the n-type impurity is not implanted at all.

Thus, the impurity can be implanted in a high density without using the resist mask 908 shown in FIG. 11C as a mask, although subsequent manufacturing steps are not described here. However, this method results in a problem in that abrasion can occur in the vicinity of the LDD regions 9236 because of the influence of hydrogen included in the insulation film 926a formed of SiN when the impurity is activated by irradiating it with laser light.

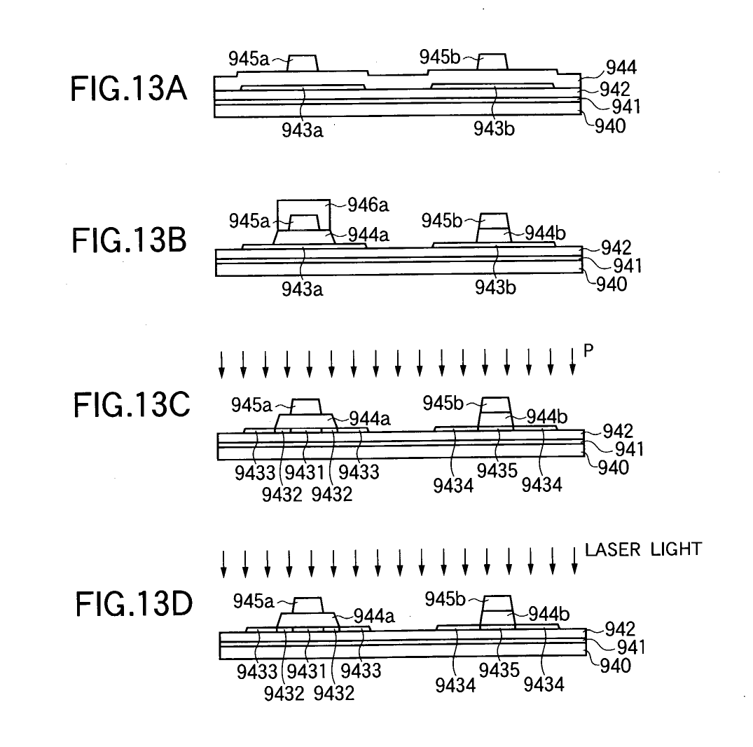

In order to solve the above-described problem, another method of manufacturing a TFT substrate has been proposed. FIGS. 13A to 13D are sectional views taken in manufacturing processes showing a third example of a method of manufacturing a TFT substrate according to the related art. FIGS. 13A to 13D show a region where an n-channel TFT having LDD regions is to be formed on the left side and show a region where an n-channel TFT having no LDD region is to be formed on the right side.

First, as shown in FIG. 13A, an underlying SiN film 941 and an SiO₂ film 942 are formed in the order listed throughout a top surface of a transparent insulated substrate 940 made of glass or the like using a plasma CVD apparatus. An amorphous silicon film is then formed throughout a top surface of the SiO₂ film 942. The amorphous silicon is then crystallized using an excimer laser to form a polysilicon film 943. Thereafter, a resist is applied to the entire surface and patterned, and dry etching is performed with a fluorine type gas using the patterned resist layer as a mask to form polysilicon films in the form of islands.

Next, the resist layer is peeled off, and a SiO₂ film is formed on the polysilicon films throughout the substrate using a plasma CVD apparatus to form an insulation film (that is referred to as gate insulation film when located under a gate electrode) 944. Then, an Al—Nd film 945 to become gate electrodes is formed throughout a top surface of the insulation film 944 using a sputtering apparatus. A resist is then applied and patterned to form resist masks in the form of gate electrodes on the Al—Nd film 945. The Al—Nd film is etched with an Al etcher using the resist masks to form gate electrodes 945a and 945b.

Next, as shown in FIG. 13B, a resist layer 946a is formed such that it covers the gate electrode 945a of the n-channel TFT to be formed with LDDs and parts of a polysilicon film 943a to become the LDD regions. The insulation film 944 is etched using the resist layer 946a and the gate electrode 945b as masks to form an insulation film 944a such that it covers parts of the polysilicon film 943a to become a channel region and LDDs in the region to form the n-channel TFT having LDDs. An insulation film 944b is also formed such that it covers a part of the polysilicon film 943b to become a channel region in the region where an n-channel TFT having no LDD is to be formed. The resist mask 946a is thereafter peeled off.

Next, as shown in FIG. 13C, an n-type impurity such as P ions is implanted at high acceleration and in a low density with an ion doping apparatus using the gate electrodes 945a and 945b as masks. Thus, the n-type impurity in a low density is implanted in source and drain regions 9433 of the n-channel TFT to be formed with LDDs and in source and drain regions 9434 of then-channel TFT to be formed with no LDD. The n-type impurity in a low density is implanted in LDD regions 9432 of the n-channel TFT to be formed with LDDs through the insulation film 944a.

Subsequently, an n-type impurity such as P ions is implanted at low acceleration and in a high density with an ion doping apparatus using the gate electrodes 945a and 945b and the insulation film 944a as masks. Thus, the n-type impurity in a high density is implanted in the source and drain regions 9433 of the n-channel TFT to be formed with LDDs and in the source and drain regions 9434 of the n-channel TFT to be formed with no LDD. The impurity is not implanted in channel regions 9431 and 9435 because the gate electrodes 945a and 945b serve as masks.

Next, as shown in FIG. 13D, the implanted impurity is irradiated with an excimer laser to activate the same. At this time, the insulation film 944a has been formed on the LDD regions 9432 while the insulation film 944 has not been formed on the source and drain regions 9433 and 9434. This results in a problem in that the laser light will be reflected in different degrees depending on regions. That is, the activation of the impurity becomes ununiform between the source and drain regions 9433 and 9434 and the LDD regions 9432 when they are irradiated with laser light under the same conditions.

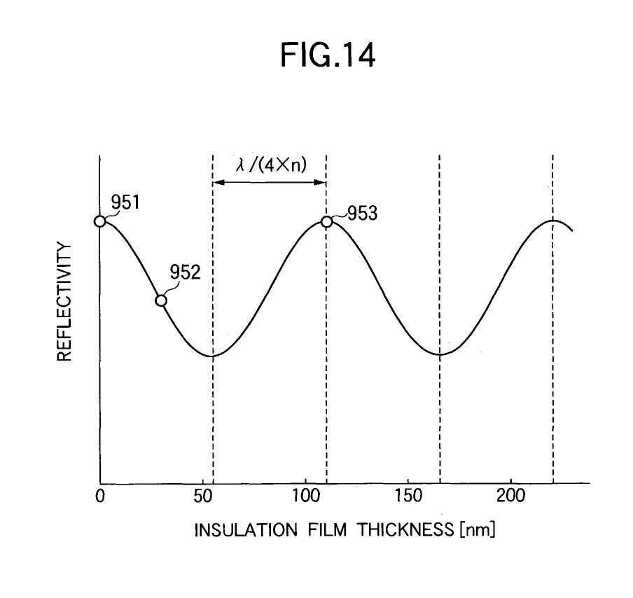

FIG. 14 is a graph showing a relationship between the thickness of an insulation film (a SiO₂ film in this case) formed on a polysilicon film and the reflectivity of the same. The ordinate axis represents the reflectivity, and the abscissa axis represents the thickness (nm) of the gate insulation film. As shown in FIG. 14, the waveform in the graph indicating changes in the reflectivity relative to the film thickness is a cosine curve having a period of λ/(2×n) where represents the wavelength of laser light and n represents the refractive index of the insulation film.

In the case of the source and drain regions 9433 and 9434, they exhibit reflectivity as indicated by a point 951 on the graph because the insulation film 944 is not formed (the insulation film thickness is 0). When the insulation film 944 is formed to a thickness of about 30 nm, they exhibit reflectivity as indicated by a point 952 on the graph. When the reflectivity varies as thus described, the activation of the impurity becomes ununiform to reduce the reliability of the device.

When the thickness of the insulation film is an integral multiple of the period of the cosine curve, the reflectivity becomes equal to the value exhibited when the insulation film 944 is not formed as indicated by a point 953 on the graph. The period λ is about 110 nm when the wavelength of the excimer laser is 308 nm and the refractive index of the insulation film (SiO₂) 944 is 1.463. That is, when the thickness of the insulation film 944 is about 110 nm for example, the reflectivity equals the value achieved when the insulation film 944 is not formed. Therefore, the implanted impurity has been uniformly activated by providing the insulation film 944 with a thickness of about 110 nm according to the related art. It is however desired to reduce the thickness of the insulation film 944 and, for example, it must be about 30 nm instead of about 110 nm in some cases.

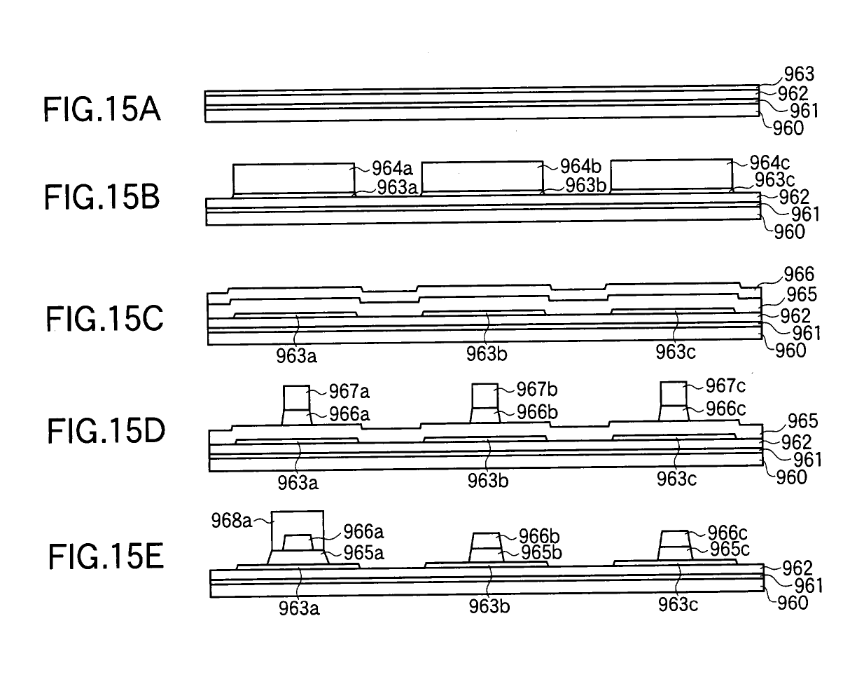

A description will now be made with reference to FIGS. 15A to 17C on an example of a method of manufacturing polysilicon TFTs in which a peripheral circuit to be driven at a low voltage and a high speed has a CMOS configuration and in which a thin film transistor for driving a pixel is an n-channel TFT. In each of the figures, steps for manufacturing an n-channel TFT having LDDs are shown on the left side; steps for manufacturing an n-channel TFT having no LDD are shown in the middle; and steps for manufacturing a p-channel TFT having no LDD are shown on the right side. The n-channel TFT having LDDs is formed in a pixel matrix section, and the n-channel TFT and p-channel TFT having no LDD are formed in a peripheral circuit section to be driven at a low voltage and a high speed. No LDD is formed on the CMOS of the peripheral circuit because degradation of characteristics attributable to the hot carrier phenomenon can be suppressed without LDDs in the peripheral circuit section to be driven at a low voltage and a high speed.

First, as shown in FIG. 15A, an underlying SiN film 961 and a SiO₂ film 962 are formed in the order listed throughout a top surface of a transparent insulated substrate 960 made of glass or the like using a plasma CVD apparatus. Subsequently, an amorphous silicon film is formed throughout a top surface of the SiO₂ film 962. The amorphous silicon is then crystallized using an excimer laser to form a polysilicon film 963.

Next, as shown in FIG. 15B, patterned resist layers 964a, 964b and 964c are formed. Dry etching is performed with a fluorine type gas using the resist layers 964a, 964b and 964c as masks to remove parts of the polysilicon film, thereby forming polysilicon films 963a, 963b and 963c in the form of islands. The resist layers 964a, 964b and 964c are thereafter peeled off.

Next, as shown in FIG. 15C, a SiO₂ film is formed on the polysilicon films 963a, 963b and 963c throughout the substrate using a plasma CVD apparatus to provide an insulation film (that serves as a gate insulation film when located under a gate electrode) 965. Next, an Al—Nd film 966 to become gate electrodes is then formed throughout a top surface of the insulation film 965 using a sputtering apparatus.

Next, as shown in FIG. 15D, a resist applied to the Al—Nd film 966 and is patterned to form resist masks 967a, 967b and 967c in the form of gate electrodes. The Al—Nd film 966 is etched with an Al etcher using the resist masks 967a, 967b and 967c to form gate electrodes 966a, 966b and 966c. The resist masks 967a, 967b and 967c are thereafter peeled off.

Next, as shown in FIG. 15E, a resist layer 968a is patterned such that it coverts parts to become LDD regions of the polysilicon film 963a in the region where the n-channel TFT having LDD is to be formed and such that it covers the gate electrode 966a. The insulation film 965 is dry-etched using the resist layer 968a and the gate electrodes 966b and 966c as masks. Thus, the insulation film 965 formed on parts of the polysilicon film 963a to become source and drain regions is removed in the region where the n-channel TFT having LDDs is to be formed, and an insulation film 965a is left on a part of polysilicon film 963a to become LDD regions and a channel region. The insulation film 965 formed on parts of the polysilicon film 963b to become source and drain regions is removed in the region to form the n-channel TFT having no LDD, and a gate insulation film 965b is left on a part of the polysilicon film 963b to become a channel region. The insulation film 965 formed on parts of the polysilicon film 963c to become source and drain regions is removed in the region to form the p-channel TFT having no LDD, and a gate insulation film 965c is left on a part of the polysilicon film 963c to become a channel region. The resist layer 968a is thereafter peeled off.

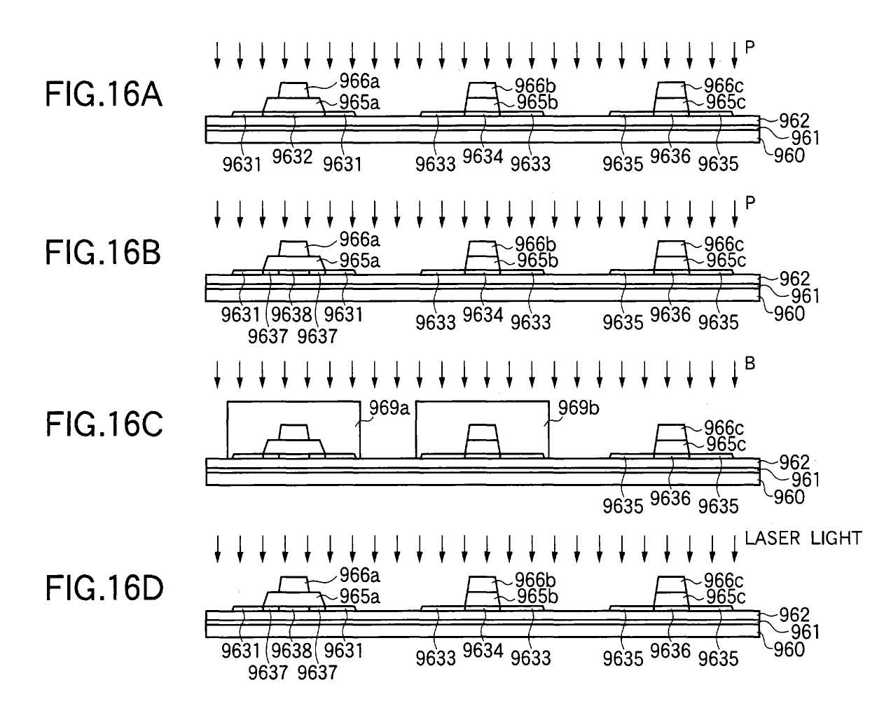

Next, as shown in FIG. 16A, an n-type impurity such as P ions is implanted at low acceleration and in a high density using an ion doping apparatus, the gate electrode 966a and the insulation film 965a serving as masks in the region to form an n-channel TFT having LDDs, the gate electrodes 966b and 966c serving as masks in the region to form the p-channel TFT having no LDD. Thus, the n-type impurity is implanted in a high density in source and drain regions 9631 of the polysilicon film 963a in the region to form the n-channel TFT having LDDs. The n-type impurity is also implanted in a high density in source and drain regions 9633 of the polysilicon film 963b in the region to form the n-channel TFT having no LDD and source and drain regions 9635 of the p-channel TFT.

Since the gate electrodes 966a, 966b and 966c serve as masks, the n-type impurity is not implanted in a part 9632 of the polysilicon film 963a to become a channel region and LDD regions in the region to form the n-channel TFT having LDDs, a channel region 9634 of the polysilicon film in the region to form the n-channel TFT having no LDD, and a part 9636 of the polysilicon film to become a channel region in the region to form the p-channel TFT having no LDD.

Next, an n-type impurity such as P ions is implanted at high acceleration and in a low density using an ion doping apparatus using the gate electrodes 966a, 966b and 966c as masks. Thus, the n-type impurity in a low density is further implanted in the source and drain regions 9633 of the n-channel TFT to be formed with LDDs, and the n-type impurity in a low density is implanted through the insulation film 965a to form LDD regions 9637 in the polysilicon film. The n-type impurity in a low density is further implanted in the source and drain regions 9633 and 9635 of the n-channel TFT and p-channel TFT to be formed with no LDD.

Next, as shown in FIG. 16C, patterned resist layers 969a and 969b are formed such that they cover the entire region to form the n-channel TFT having LDDs and the entire region to form then-channel TFT having no LDD, respectively. A p-type impurity such as boron (B) ions is then implanted at low acceleration and in a high density with an ion doping apparatus using the resist layers 969a and 969b and the gate electrode 966c as masks. Thus, the p-type impurity is implanted in the source and drain regions 9635 of the p-channel TFT to be formed with no LDD. Since the n-type impurity has been implanted in the source and drain regions 9635, an inversion from the n-type to the p-type is caused by implanting the p-type impurity in a greater amount. Since the gate electrode 966c serves as a mask, the p-type impurity is not implanted in the channel region 9636 of the polysilicon film 963c. The resist masks 969a and 969b are thereafter peeled off.

Next, as shown in FIG. 16D, the source and drain regions 9631, 9633 and 9635 and the LDD regions 9637 are irradiated with laser light from an excimer laser apparatus to activate the implanted n-type and p-type impurities.

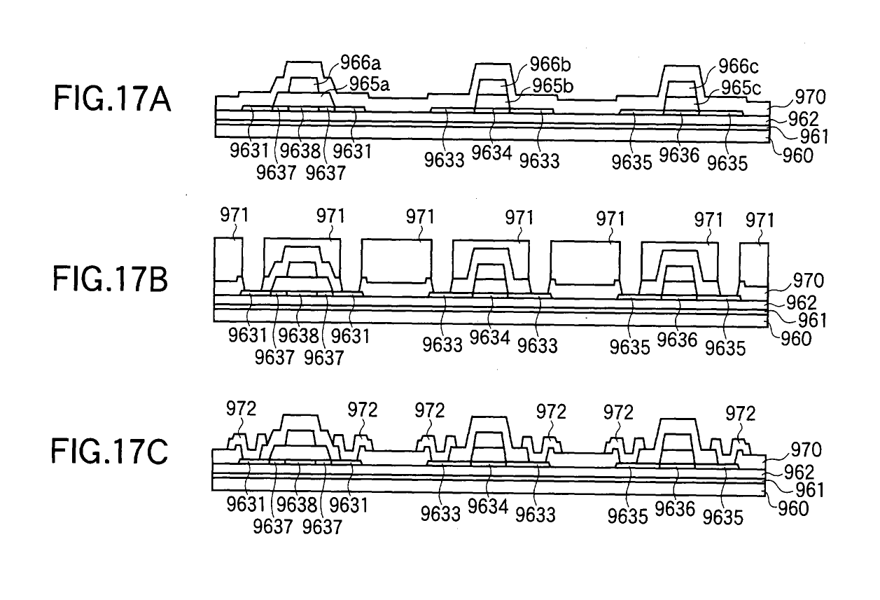

As shown in FIG. 17A, for example, a SiO₂ film is then formed on the gate electrodes 966a, 966b and 966c throughout the substrate using a plasma CVD apparatus to provide a first layer insulation film 970.

Next, as shown in FIG. 17B, a resist mask 971 is formed to provide contact holes, and the first layer insulation film 970 is etched to remove parts of the first layer insulation film 970 formed on the source and drain regions of the polysilicon film of each of the TFTs.

Next, as shown in FIG. 17C, after peeling off the resist mask 971, a conductive thin film is formed to provide source and drain electrodes. A resist is then applied and patterned, and the conductive thin film is etched using the patterned resist layer to form source and drain electrodes 972. Although not shown, a TFT substrate for a liquid crystal display is completed by forming a second layer insulation film on the entire surface and forming transparent pixel electrodes after providing contact holes.

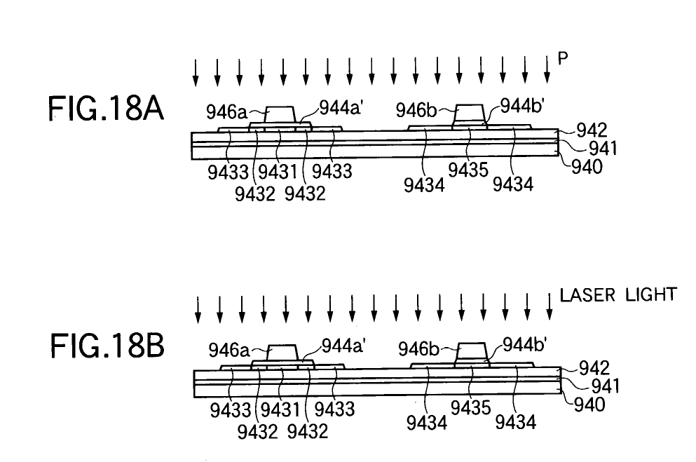

Recently, there are demands for further reduction of power consumption and peripheral circuit sections operating at higher speeds, and it is necessary to reduce the thickness of gate insulation films and to thereby suppress a driving voltage in order to satisfy such demands. However, two problems as described below will arise when gate insulation films having a smaller thickness are used in the above-described manufacturing method. Referring to the first problem, since an impurity in a high density is implanted using an insulation film (gate insulation films) as a mask in the above-described manufacturing method, a great amount of the impurity is implanted even in LDD regions when the thickness of the insulation film is thin. FIG. 18A shows an example in which the thickness of the insulation film 944a shown in FIG. 13C is made thin. As shown in FIG. 18A, when an n-type impurity is implanted at low acceleration and in a high density, a considerably great amount of the impurity is implanted in LDD regions 9432 under an insulation film 944a′ through the insulation film 944a′ whose masking ability has been reduced as a result of a reduction of the thickness thereof, and the same regions become disabled as LDDs. No problem occurs on the n-channel TFT to be formed with no LDD even when the thickness of the gate insulation film 944b is reduced to form a gate insulation film 944b′ because the gate insulation film is not used as a mask.

The second problem is the fact that optical interference can change the reflectivity of the surface of the thin insulation film (e.g., SiO₂) 944a′ against laser light emitted by an excimer laser for laser activation. Because of this problem, a difference occurs between energies applied to source and drain regions doped with an impurity in a high density and LDD regions doped with the impurity in a low density, and this makes it difficult to activate both of the regions simultaneously and sufficiently. As shown in FIG. 18B, while the top surface of the source and drain regions 9433 is exposed, the top surface of the LDD regions 9432 is covered by the gate insulation film 944a′. As a result, even when the entire surface of the substrate is irradiated with laser light, there will be a difference in degrees of reflection of the irradiating laser light between the source and drain regions 9433 and the LDD regions 9432. As shown in FIG. 14, it is inevitable to increase the thickness of the insulation film 944a′ to provide the source and drain regions 9433 and the LDD regions 9432 with the same reflectivity.

### SUMMARY OF THE INVENTION

It is an object of the invention to provide a thin film transistor device having good characteristics and high reliability, a method of manufacturing the same, and a thin film transistor substrate and a display having the same.

The above object is achieved by a method of manufacturing a thin film transistor device, characterized in that it has the steps of forming a semiconductor layer having a predetermined configuration on a substrate, forming a first insulation film on the semiconductor layer, forming a gate electrode of a thin film transistor of a first conductivity type on the first insulation film, forming source and drain regions and low density impurity regions by implanting an impurity of the first conductivity type in the semiconductor layer using the gate electrode as a mask, forming a mask layer on the low density impurity regions, forming a gate insulation film by patterning the first insulation film using the mask layer, implanting the impurity of the first conductivity type in the source and drain regions using the mask layer continuously, and forming a second insulation film having a predetermined thickness on the source and drain regions and the low density impurity regions after removing the mask layer and irradiating the same with laser light to activate the impurity in the source and drain regions and the low density impurity regions.

### BRIEF DESCRIPTION OF THE DRAWAINGS

FIG. 1 shows a schematic configuration of a liquid crystal display in a first embodiment of the invention;

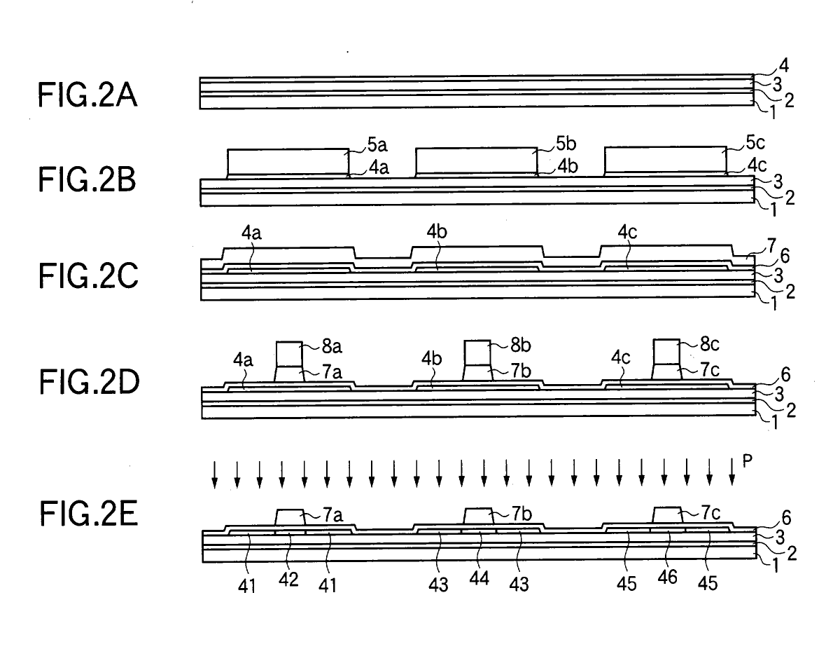

FIGS. 2A to 2E are sectional views taken in processes showing a method of manufacturing thin film transistor devices and a thin film transistor substrate having the same in the first embodiment of the invention;

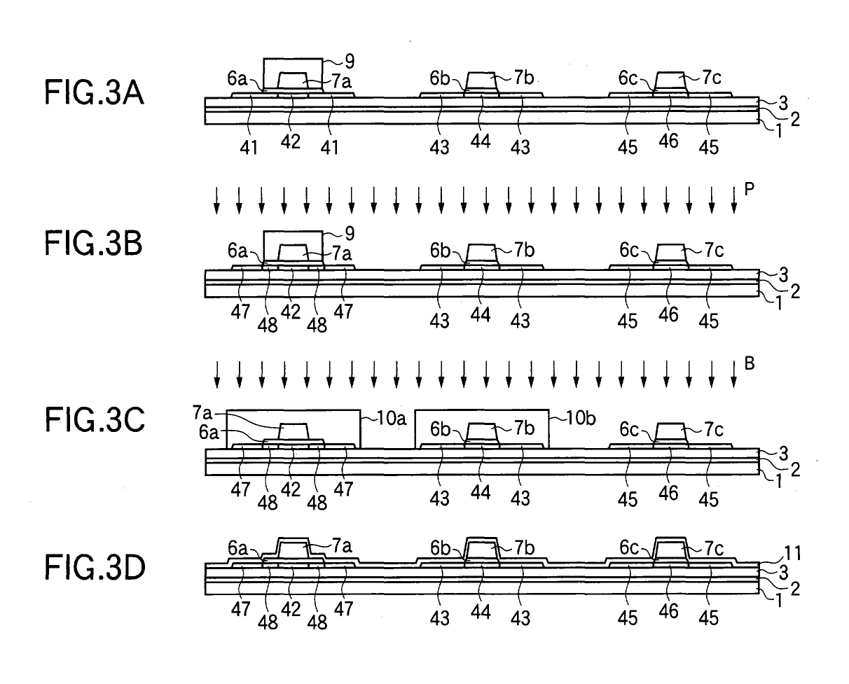

FIGS. 3A to 3D are sectional views taken in processes showing the method of manufacturing thin film transistor devices and a thin film transistor substrate having the same in the first embodiment of the invention;

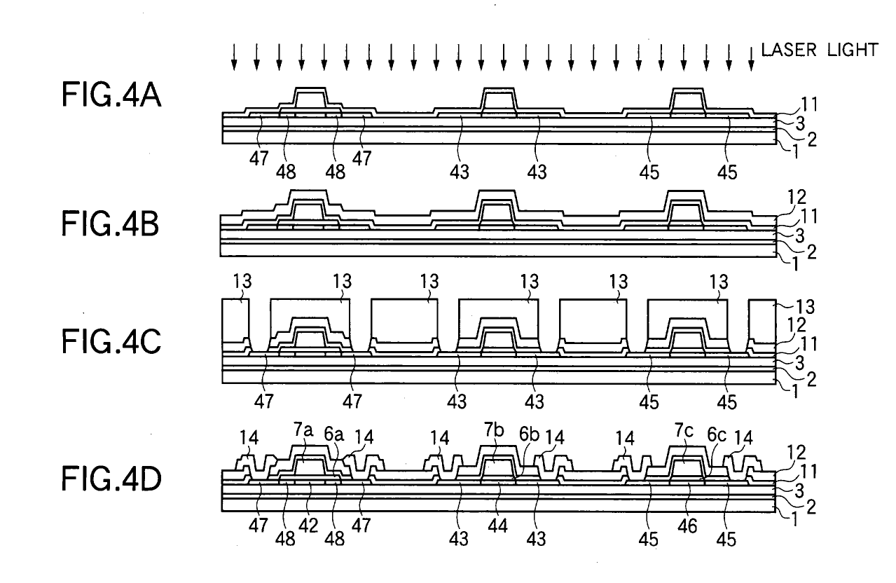

FIGS. 4A to 4D are sectional views taken in processes showing the method of manufacturing thin film transistor devices and a thin film transistor substrate having the same in the first embodiment of the invention;

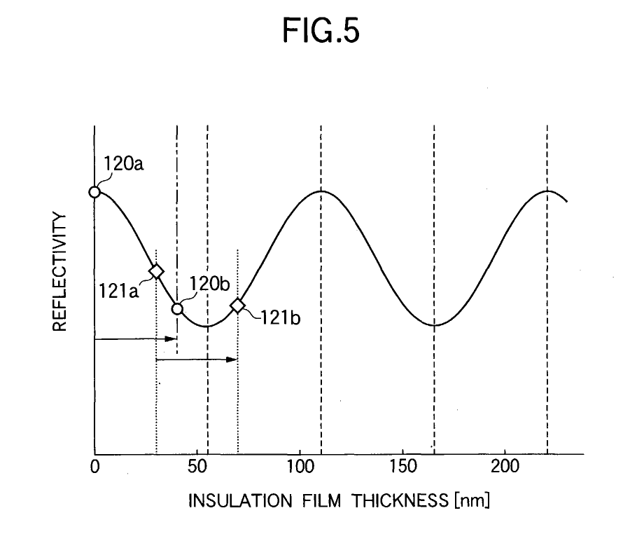

FIG. 5 shows a relationship between the thickness of an insulation film and reflectivity according to the method of manufacturing thin film transistor devices and a thin film transistor substrate having the same in the first embodiment of the invention;

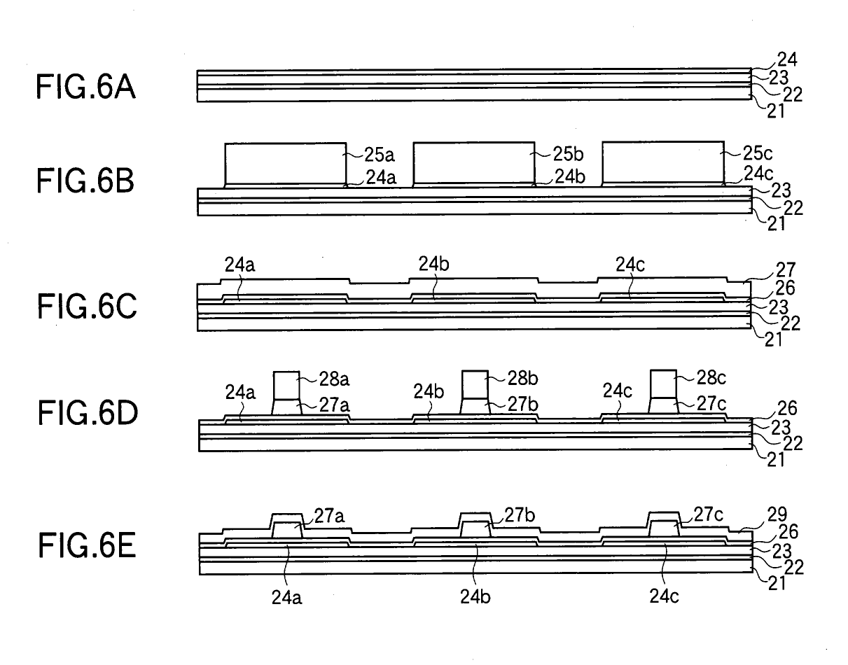

FIGS. 6A to 6E are sectional views taken in processes showing a method of manufacturing thin film transistor devices and a thin film transistor substrate having the same in a second embodiment of the invention;

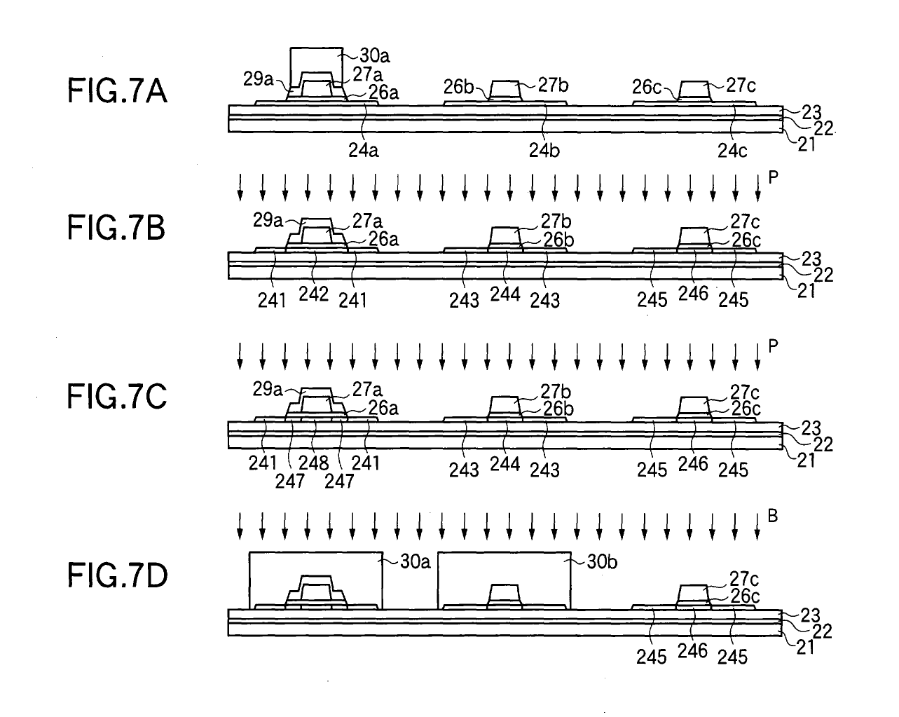

FIGS. 7A to 7D are sectional views taken in processes showing the method of manufacturing thin film transistor devices and a thin film transistor substrate having the same in the second embodiment of the invention;

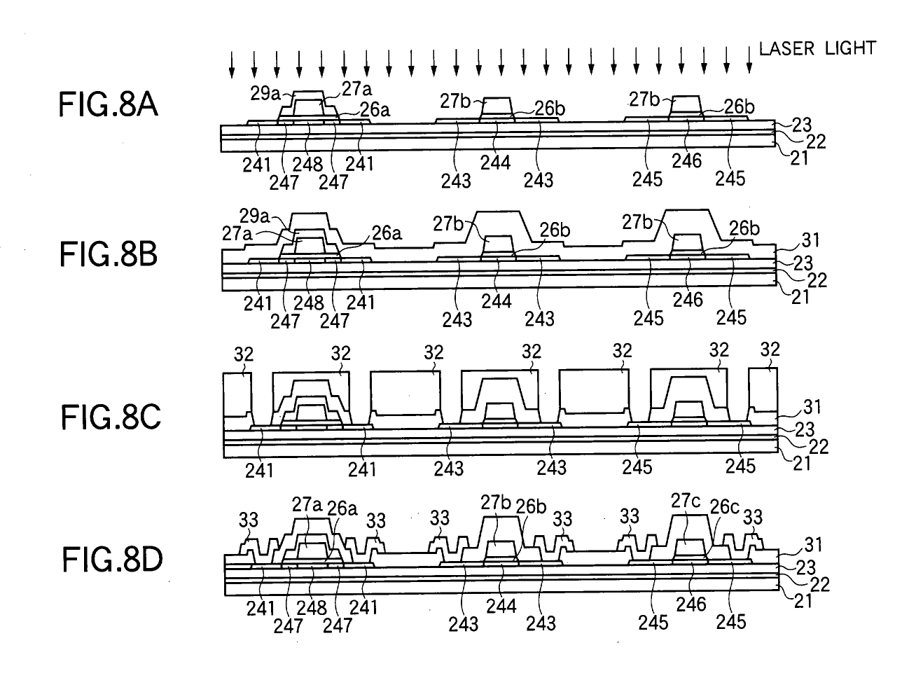

FIGS. 8A to 8D are sectional views taken in processes showing the method of manufacturing thin film transistor devices and a thin film transistor substrate having the same in the second embodiment of the invention;

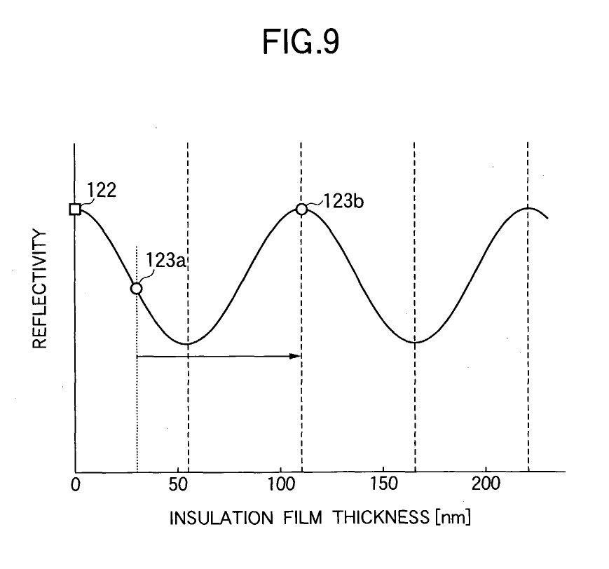

FIG. 9 shows a relationship between the thickness of an insulation film and reflectivity according to the method of manufacturing thin film transistor devices and a thin film transistor substrate having the same in the second embodiment of the invention;

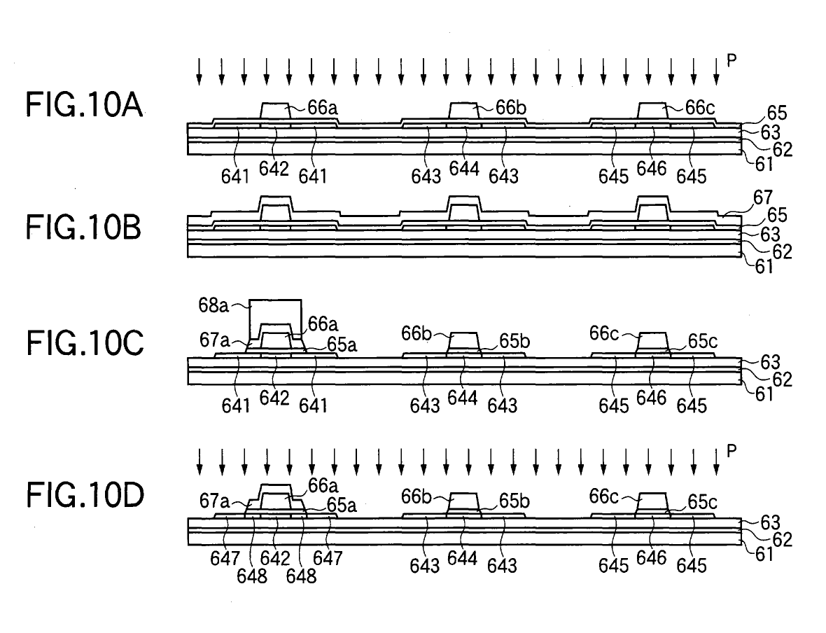

FIGS. 10A to 10D are sectional views taken in processes showing a method of manufacturing thin film transistor devices and a thin film transistor substrate having the same in a third embodiment of the invention;

FIGS. 11A to 11D are sectional views taken in manufacturing processes illustrating a method of manufacturing a TFT substrate as a first example of the related art;

FIGS. 12A to 12C are sectional views taken in manufacturing processes illustrating a method of manufacturing a TFT substrate as a second example of the related art;

FIGS. 13A to 13D are sectional views taken in manufacturing processes illustrating a method of manufacturing a TFT substrate as a third example of the related art;

FIG. 14 is a graph showing a relationship between the thickness of an insulation film and reflectivity in the third example of the related art;

FIGS. 15A to 15E are sectional views taken in manufacturing processes illustrating the method of manufacturing a TFT substrate as the third example of the related art;

FIGS. 16A to 16D are sectional views taken in manufacturing processes illustrating a method of manufacturing a TFT substrate as a fourth example of the related art;

FIGS. 17A to 17C are sectional views taken in manufacturing processes illustrating the method of manufacturing a TFT substrate as the fourth example of the related art; and

FIGS. 18A and 18B illustrate problems with a method of manufacturing a TFT substrate according to the related art.

### DESCRIPTION OF THE PREFERRED EMBODIMENTS

[First Embodiment]

A description will now be made with reference to FIGS. 1 to 5 on thin film transistor devices, a method of manufacturing the same, and a thin film transistor substrate and a liquid crystal display as a display having the same in a first embodiment of the invention. A liquid crystal display in the present embodiment will be first described with reference to FIG. 1. A liquid crystal display 100 has a TFT substrate 110 and an opposite substrate (not shown) that is combined with the TFT substrate 110 in a face-to-face relationship with a predetermined cell gap left therebetween. A liquid crystal is sealed between the substrates. The TFT substrate 110 has a pixel matrix region 111 in which a plurality of pixels are arranged in the form of a matrix and a drain driving circuit 112 and a gate driving circuit 113 formed in a peripheral circuit region around the pixel matrix area 111. A pixel driving TFT is formed in each of the plurality of pixels in the pixel matrix region 111. A drain electrode of each pixel driving TFT is connected to a predetermined drain bus line extending from the data driving circuit 113, and a gate electrode of each pixel driving TFT is connected to a predetermined gate bus line extending from the gate driving circuit 112. A source electrode of each pixel driving TFT is connected to a pixel electrode (not shown) provided at the respective pixel.

The drain driving circuit 112 and the gate driving circuit 113 include a circuit in which TFT devices for a low voltage to be operated at a high speed are formed in a CMOS configuration and a circuit constituted by TFT devices for a high voltage to be operated at a high voltage. The pixel matrix region 111 is constituted by TFT devices for a high voltage.

A description will now be made with reference to FIGS. 2A to 4D on a method of manufacturing thin film transistor devices and a thin film transistor substrate having the same in the present embodiment. FIGS. 2A to 4D show a method of manufacturing polysilicon TFTs in which a peripheral circuit to be driven at a low voltage and a high speed has a CMOS configuration and in which a thin film transistor for driving a pixel is an n-channel TFT. In each of the figures, steps for manufacturing an n-channel TFT having LDDs are shown on the left side; steps for manufacturing an n-channel TFT having no LDD are shown in the middle; and steps for manufacturing a p-channel TFT having no LDD are shown on the right side. The n-channel TFT having LDDs is formed in the pixel matrix region 111, and the n-channel TFT and p-channel TFT having no LDD are formed in the gate driving circuit 113 and the drain driving circuit 112, for example.

First, as shown in FIG. 2A, an underlying SiN film 2 having a thickness of about 50 nm and a SiO₂ film 3 having a thickness of about 200 nm are formed in the order listed throughout a top surface of a transparent insulated substrate 1 made of glass or the like using a plasma CVD apparatus. Subsequently, an amorphous silicon film of about 40 nm is formed throughout a top surface of the SiO₂ film 3. The amorphous silicon is then crystallized using an excimer laser to form a polysilicon film 4.

Next, as shown in FIG. 2B, a resist is applied and patterned to form patterned resist layers 5a, 5b and 5c. Dry etching is performed with a fluorine type gas using the resist layers 5a, 5b and 5c as masks to remove parts of the polysilicon film, thereby forming polysilicon films 4a, 4b and 4c in the form of islands. The resist layers 5a, 5b and 5c are thereafter peeled off.

Next, as shown in FIG. 2C, a SiO₂ film is formed on the polysilicon films 4a, 4b and 4c throughout the substrate using a plasma CVD apparatus to provide an insulation film (that serves as a gate insulation film when located under a gate electrode) 6 having a thickness of about 30 nm. The insulation film 6 is formed with a thickness thinner than that of the insulation film 965 shown in FIGS. 15A to 15E according to the related art, for example. An Al—Nd film 7 to become gate electrodes is formed to a thickness of about 300 nm throughout a top surface of the insulation film 6 using a sputtering apparatus.

Next, as shown in FIG. 2D, a resist is applied on to the Al—Nd film 7 and is patterned to form resist masks 8a, 8b and 8c in the form of gate electrodes. The Al—Nd film 7 is etched with an Al etcher using the resist masks 8a, 8b and 8c to form gate electrodes 7a, 7b and 7c. The resist masks 8a, 8b and 8c are thereafter peeled off.

As shown in FIG. 2E, for example, the polysilicon films 4a, 4b and 4c are doped with P ions in a low density as an n-type impurity through the insulation film 6 with an ion doping apparatus using the gate electrodes 7a, 7b and 7c as masks (first doping). The doping is performed at an accelerating energy of 30 keV and in a dose amount of 5×10¹³ cm². In the region where the n-channel TFT having LDDs is to be formed, the n-type impurity is implanted in parts 41 of the polysilicon film 4a that are to become LDD regions and source and drain regions. The n-type impurity is also implanted in parts 43 and 45 of the respective polysilicon films 4b and 4c that are to become source and drain regions in the regions where the n-channel TFT and the p-channel TFT having no LDD are to be formed. The n-type impurity is not implanted in parts 42, 44 and 46 that are to become channel regions because the gate electrodes 7a, 7b and 7c serve as masks.

Next, as shown in FIG. 3A, a resist layer 9 is patterned such that it coverts parts of the polysilicon film 4a to become LDD regions and the gate electrode 7a in the region where the n-channel TFT having LDD is to be formed. The insulation film 6 is dry-etched using a fluorine type gas, the resist layer 9 and the gate electrodes 7b and 7c serving as masks. Thus, the insulation film 6 formed on parts of the polysilicon film 4a to become source and drain regions is removed in the region where the n-channel TFT having LDDs is to be formed, and an insulation film 6a is left on a part of polysilicon film 4a to become LDD regions and a channel region. The insulation film 6 formed on parts of the polysilicon film 4b to become source and drain regions is removed in the region to form the n-channel TFT having no LDD, and a gate insulation film 6b is left on a part of the polysilicon film 4b to become a channel region. The insulation film 6 formed on parts of the polysilicon film 4c to become source and drain regions is removed in the region to form the p-channel TFT having no LDD, and a gate insulation film 6c is left on a part of the polysilicon film 4c to become a channel region.

Subsequently, as shown in FIG. 3B, for example, an n-type impurity such as P ions is implanted in a high density with an ion doping apparatus using the resist layer 9 again as a mask for the region to form the n-channel TFT having LDDs and using the gate electrodes 7b and 7c as masks for the regions to form the n-channel TFT and the p-channel TFT having no LDD (second doping). The second doping is performed at an acceleration energy of 10 keV and a dose amount of 1×10¹⁵ cm⁻², for example. At this time, the n-type impurity is also implanted in a high density in source and drain regions 43 of the polysilicon film 4b in the region to form the n-channel TFT having no LDD and source and drain regions 45 of the p-channel TFT.

Thus, in the polysilicon film 4a in the region to form the n-channel TFT having LDDs, there is formed source and drain regions 47 in which the n-type impurity is implanted in a high density, LDD regions 48 in which the n-type impurity is implanted only at the first doping, and a channel region 42 in which the n-type impurity is not implanted at all. In the regions to form the n-channel TFT and the p-channel TFT having no LDD, the n-type impurity is implanted twice in source and drain regions 43 and 45. The n-type impurity is not implanted in channel regions 44 and 46 of the regions to form the n-channel TFT and the p-channel TFT having no LDD because the gate electrodes 7b and 7c serve as masks. The insulation film 6 may be etched after the second implantation of the n-type impurity. While doping is performed using the resist layer 9 as a mask, alteration of the resist layer 8 can be suppressed because the doping is performed without the intervention of the insulation film 6. Therefore, no residual resist remains after an ashing process.

After removing the resist layer 9 through ashing, as shown in FIG. 3C, patterned resist layers 10a and 10b are formed such that they cover the entire region to form the n-channel TFT having LDDs and the entire region to form the n-channel TFT having no LDD, respectively. A p-type impurity such as boron (B) ions is then implanted in a high density with an ion doping apparatus using the resist layers 10a and 10b and the gate electrode 7c as masks. For example, the doping is performed at an acceleration energy of 10 keV and in a dose amount of 2×10¹⁵ cm⁻². Thus, the p-type impurity is implanted in the source and drain regions 45 of the p-channel TFT to be formed with no LDD. Since the n-type impurity has been implanted in the source and drain regions 45, an inversion from the n-type to the p-type is caused by implanting the p-type impurity in a greater amount. The p-type impurity is not implanted in the channel region 46 of the polysilicon film 4c because the gate electrode 7c serves as a mask. The resist masks 10a and 10b are thereafter peeled off.

Next, as shown in FIG. 3D, a SiO₂ film as an interlayer insulation film 11 is formed to a thickness of about 40 nm using a plasma CVD apparatus. The reason for forming the SiO₂ film having a thickness of about 40 nm will be described with reference to FIG. 5. In FIG. 5, the ordinate axis represents reflectivity, and the abscissa axis represents the thickness (nm) of the insulation film made of SiO₂. The thickness of the insulation film 6 is 30 nm, and the reflectivity of the LDD regions 48 provided under the insulation film 6 before the formation of the interlayer insulation film 11 is a value indicated by a point 121a as shown in FIG. 5. Since the insulation film 6 does not resides on the source and drain regions 47, the reflectivity of the same is a value as indicated by a point 120a. When the reflectivity of the source and drain regions 47 is different from the reflectivity of the LDD regions 48, the activation of the impurity through irradiation with a laser light becomes ununiform depending on regions as already described.

Under such circumstances, when the interlayer insulation film (first interlayer insulation film) 11 having a thickness of about 40 nm is formed, the thickness of the SiO₂ film on the source and drain regions 47 becomes 40 nm, and the value of their reflectivity changes from the value indicated by the point 120a to a value indicated by a point 120b along the reflectivity curve. On the contrary, the thickness of the SiO₂ film on the LDD regions 48 becomes 70 nm, and the value of their reflectivity changes from the value indicated by the point 121a to a value indicated by a point 121b along the reflectivity curve. At this time, the values of reflectivity indicated by the points 120b and point 121b are substantially equal to each other. Therefore, when irradiation with a laser is performed thereafter, the impurities are substantially uniformly activated in the source and drain regions and the LDD regions, which allows conditions for laser irradiation to be determined easily.

Next, as shown in FIG. 4A, the source and drain regions 43, 45 and 47 and the LDD regions 48 are irradiated with laser light using an excimer laser to activate the n-type and p-type impurities implanted.

As shown in FIG. 4B, for example, a SiN film is then formed to a thickness of about 370 nm on the gate electrodes 7a, 7b and 7c throughout the substrate using a plasma CVD apparatus to form a second interlayer insulation film 12 including hydrogen. A thermal process is then performed at 80° C. for two hours in a nitrogen atmosphere. An annealing process or hydrogen plasma process in a hydrogen atmosphere is used as a method of hydrogenating the second interlayer insulation film 12. It is not necessary to form the second interlayer insulation film 12 when the first interlayer insulation film 11 is formed with a sufficient thickness.

Next, as shown in FIG. 4C, a resist mask 13 for providing contact holes is formed, and dry etching is performed using a fluorine type gas to remove parts of the first interlayer insulation film 11 and the second interlayer insulation film 12, thereby providing contact holes for the source and drain regions 47, 43 and 45.

Next, as shown in FIG. 4D, after peeling off the resist mask 13, a Ti film, an Al film and another Ti film are formed in the order listed to thicknesses of about 100 nm, 200 nm and 100 nm respectively using a sputtering apparatus, the films serving as conductive thin films for forming source and drain electrodes. A resist is then applied and patterned, and the conductive thin films are etched with a chlorine type gas using the patterned resist layer as a mask to form source and drain electrodes 14.

Next, a SiN film is formed to a thickness of about 400 nm as a third interlayer insulation film (not shown). A resist is then applied; the resist layer is patterned through exposure; and the SiN film is etched through dry etching with a fluorine type gas using the patterned resist layer as a mask to form contact holes. After peeling off the resist layer, an ITO film is formed to a thickness of about 70 nm using a sputtering apparatus. A resist is then applied and is exposed to form a patterned resist layer, and the ITO film is etched with an ITO etcher using the patterned resist layer as a mask. Thus, thin film transistor devices and a thin film transistor substrate and a liquid crystal display having the same in the present embodiment are formed.

In the n-channel TFT formed with LDDs manufactured according to the method of manufacture in the present embodiment, a buffer layer that is constituted by the underlying SiN film 2 and the SiO₂ film 3 is formed on the transparent insulated substrate 1. The polysilicon film 4 is formed on the buffer layer, and the source and drain regions 47, the LDD regions 48 and the channel region 42 are formed in the polysilicon film 4. The gate insulation film 6a is formed on the LDD regions 48 and the channel region 42 in the polysilicon film 4. The gate electrode 7a is formed on the gate insulation film 6a on the channel region 42. The first interlayer insulation film 11 and the second interlayer insulation film 12 are formed in the order listed on the source and drain regions 47, the gate insulation film 6a and the gate electrode 7a. The first interlayer insulation film 11 and the second interlayer insulation film 12 are provided with contact holes to form the source and drain electrodes 14 that are in contact with the source and drain regions 47 of the polysilicon film 4.

In the n-channel TFT formed with no LDD manufactured according to the method of manufacture in the present embodiment, a buffer layer that is constituted by the underlying SiN film 2 and the SiO₂ film 3 is formed on the transparent insulated substrate 1. The polysilicon film 4 is formed on the buffer layer, and the source and drain regions 43 and the channel region 44 are formed in the polysilicon film 4. The gate insulation film 6b and the gate electrode 7b are formed in the order listed on the channel region 44 of the polysilicon film 4. The first interlayer insulation film 11 and the second interlayer insulation film 12 are formed in the order listed on the source and drain regions 43 and the gate electrode 7b. The first interlayer insulation film 11 and the second interlayer insulation film 12 are provided with contact holes to form the source and drain electrodes 14 that are in contact with the source and drain regions 43 of the polysilicon film 4.

In the p-channel TFT formed with no LDD manufactured according to the method of manufacture in the present embodiment, a buffer layer that is constituted by the underlying SiN film 2 and the SiO₂ film 3 is formed on the transparent insulated substrate 1. The polysilicon film 4 is formed on the buffer layer, and the source and drain regions 45 and the channel region 46 are formed in the polysilicon film 4. The gate insulation film 6c and the gate electrode 7c are formed in the order listed on the channel region 46 in the polysilicon film 4. The first interlayer insulation film 11 and the second interlayer insulation film 12 are formed in the order listed on the source and drain regions 45 and the gate electrode 7c. The first interlayer insulation film 11 and the second interlayer insulation film 12 are provided with contact holes to form the source and drain electrodes 14 that are in contact with the source and drain regions 45 of the polysilicon film 4.

As described above, the method of manufacturing TFT devices and a TFT substrate having the same in the present embodiment is characterized in that an n-type impurity is (implanted in a high density using a resist mask for etching an insulation film (a gate insulation film) after a gate electrode is formed and in that it is activated with a laser after forming an SiO₂ film as a first layer insulation film. According to the present method of manufacture, the resist mask for etching is also used as a mask for implanting an impurity as it is, which makes it possible to prevent the problem of excessive implantation of the n-type impurity in the LDD regions even if the insulation film 6 is thin without adding a photolithographic process, although there is one additional ashing process.

Since ion implantation is performed after etching the insulation film 6 as a resist mask, doping does not occur through the insulation film 6 during ion implantation. It is therefore possible to reduce the time required for ion implantation and to reduce energy for accelerating the impurity. Since this suppresses alteration of the resist used as a mask, ashing can be easily and reliably performed. Further, as described with reference to FIG. 5, the degrees of reflection of laser light at the high density impurity-implanted regions that are source and drain regions and the LDD regions can be made substantially equal by changing the thickness of the SiO₂ film that is the first layer insulation film in accordance with the gate insulation film. That is, those regions can be simultaneously and sufficiently activated.

[Second Embodiment]

A description will now be made with reference to FIGS. 6A to 9 on thin film transistor devices, a method of manufacturing the same, and a thin film transistor substrate having the same in a second embodiment of the invention. An LCD having a TFT substrate in the present embodiment will not be described because it has the same configuration as that of the liquid crystal display 100 shown in FIG. 1 in the first embodiment.

FIGS. 6A to 8D show a method of manufacturing polysilicon TFTs in which a peripheral circuit to be driven at a low voltage and a high speed has a CMOS configuration and in which a thin film transistor for driving a pixel is an n-channel TFT. In each of the figures, steps for manufacturing an n-channel TFT having LDDs are shown on the left side; steps for manufacturing an n-channel TFT having no LDD are shown in the middle; and steps for manufacturing a p-channel TFT having no LDD are shown on the right side. The n-channel TFT having LDDs is formed in a pixel matrix region 111, and the n-channel TFT and p-channel TFT having no LDD are formed in a gate driving circuit 113 and a drain driving circuit 112, for example.

First, as shown in FIG. 6A, an underlying SiN film 22 having a thickness of about 50 nm and a SiO₂ film 23 having a thickness of about 200 nm are formed in the order listed throughout a top surface of a transparent insulated substrate 21 made of glass or the like using a plasma CVD apparatus. Subsequently, an amorphous silicon film of about 40 nm is formed throughout a top surface of the SiO₂ film 23. The amorphous silicon is then crystallized using an excimer laser to form a polysilicon film 24.

Next, as shown in FIG. 6B, a resist is applied and patterned to form patterned resist layers 25a, 25b and 25c. Dry etching is performed with a fluorine type gas using the resist layers 25a, 25b and 25c as masks to remove parts of the polysilicon film, thereby forming polysilicon films 24a, 24b and 24c in the form of islands. The resist layers 25a, 25b and 25c are thereafter peeled off.

Next, as shown in FIG. 6C, a SiO₂ film is formed on the polysilicon films 24a, 24b and 24c throughout the substrate using a plasma CVD apparatus to provide an insulation film (that serves as a gate insulation film when located under a gate electrode) 26 having a thickness of about 30 nm. The insulation film 26 is formed with a thickness thinner than that of the insulation film 965 shown in FIGS. 15A to 15E according to the related art, for example. An Al—Nd film 27 to become gate electrodes is formed to a thickness of about 300 nm throughout a top surface of the insulation film 26 using a sputtering apparatus.

Next, as shown in FIG. 6D, a resist is applied on to the Al—Nd film 27 and is patterned to form resist masks 28a, 28b and 28c in the form of gate electrodes. The Al—Nd film 27 is etched with an Al etcher using the resist masks 28a, 28b and 28c to form gate electrodes 27a, 27b and 27c. The resist masks 28a, 28b and 28c are thereafter peeled off.

Next, as shown in FIG. 6E, a SiO₂ film is formed to a thickness of about 80 nm using a plasma CVD apparatus to form a first layer insulation film 29.

Next, as shown in FIG. 7A, a resist layer 30a is formed by patterning a coated resist so as to cover the parts of LDD forming regions and channel forming regions of the polysilicon film 24a and the gate electrode 27a. SiO₂ serving as the first interlayer insulation film 29 and the insulation film 26 is dry-etched with a fluorine type gas using the resist layer 30a as a mask. Thus, the first interlayer insulation film 29 and the insulation film 26 formed on parts of the polysilicon film 24a to become source and drain regions are removed in the region to form the n-channel TFT having LDDs, and a first insulation film 29a and an insulation film 26a are left on a part of polysilicon film 24a to become LDD regions and a channel region.

The first interlayer insulation film 29 and the insulation film 26 formed on parts of the polysilicon film 24b to become source and drain regions are removed in the region to form the n-channel TFT having no LDD, and a gate insulation film 26b is left on a part of the polysilicon film 24b to become a channel region. The first interlayer insulation film 29 and the insulation film 26 formed on parts of the polysilicon film 24c to become source and drain regions are removed in the region to form the p-channel TFT having no LDD, and a gate insulation film 26c is left on a part of the polysilicon film 24c to become a channel region.

After the resist layer 30a is peeled off, as shown in FIG. 7B, an n-type impurity such as P ions is implanted in a high density with an ion doping apparatus using the first interlayer insulation film 29a as a mask for the region to form the n-channel TFT having LDDs and using the gate electrodes 27b and 27c as masks for the regions to form the n-channel TFT and the p-channel TFT having no LDD. The doping is performed at an acceleration energy of 10 keV and a dose amount of 1×10¹⁵ cm⁻², for example. At this time, the n-type impurity is also implanted in a high density in source and drain regions 243 of the polysilicon film 24b in the region to form the n-channel TFT having no LDD and source and drain regions 245 of the p-channel TFT.

Since the first interlayer insulation film 29a and the gate electrodes 27a, 27b and 27c serve as masks, the n-type impurity is not implanted in a part 242 of the polysilicon film 24a to become LDD regions and a channel region in the region to form the n-channel TFT having LDDs, a channel region 244 of the polysilicon film 24b in the region to form the n-channel TFT having no LDD, and a part 246 of the polysilicon film 24c to become a channel region in the region to form a p-channel TFT having no LDD.

Next, as shown in FIG. 7C, an n-type impurity such as P ions is implanted at an acceleration energy of 70 keV and in a dose amount of 5×10¹³ cm⁻² with an ion doping apparatus using the first interlayer insulation film 29a as a mask for the region to form the n-channel TFT having LDDs and using the gate electrodes 27b and 27c as masks for the regions to form the n-channel TFT and the p-channel TFT having no LDD. Thus, in the region to form the n-channel having LDDs, LDD regions 247 are formed in the polysilicon film 24a. At this time, the n-type impurity is not implanted in the channel regions 248, 244 and 246 because the gate electrodes 27a, 27b and 27c serve as masks.

Next, as shown in FIG. 7D, patterned resist layers 30a and 30b are formed such that they cover the entire region to form the n-channel TFT having LDDs and the entire region to form then-channel TFT having no LDD, respectively. A p-type impurity such as boron (B) ions is then implanted in a high density with an ion doping apparatus using the resist layers 30a and 30b and the gate electrode 27c as masks. For example, the doping is performed at an acceleration energy of 10 keV and in a dose amount of 2×10⁵ cm⁻². Thus, the p-type impurity is implanted in the source and drain regions 245 of the p-channel TFT to be formed with no LDD. Since the n-type impurity has been implanted in the source and drain regions 245, an inversion from the n-type to the p-type is caused by implanting the p-type impurity in a greater amount. The p-type impurity is not implanted in the channel region 246 of the polysilicon film 24c because the gate electrode 27c serves as a mask. The resist masks 30a and 30b are thereafter peeled off.

Next, as shown in FIG. 8A, the source and drain regions 241, 243 and 245 and the LDD regions 247 are irradiated with laser light using an excimer laser apparatus to activate the n-type and p-type impurities implanted therein. At this time, the gate insulation film 26a having a thickness of about 30 nm and the first interlayer insulation film 29a having a thickness of about 80 nm made of SiO₂ are provided on the LDD regions 247 of the n-channel TFT to be formed with LDDs. No SiO₂ film exists on the source and drain regions 241.

The reason for employing such a film configuration will be described with reference to FIG. 9. In FIG. 9, the ordinate axis represents reflectivity, and the abscissa axis represents the thickness (nm) of the insulation films made of SiO₂. Since the SiO₂ film thickness is 0 above the source and drain regions 241, their reflectivity is a value as indicated by a point 122 in FIG. 9. On the contrary, the SiO₂ film of 30 nm is initially formed on the LDD regions 247, and the reflectivity of the LDD regions 247 is a value as indicated by a point 123a in FIG. 9. Since this results in a difference in reflectivity between the source and drain regions 241 and the LDD regions 247, it is difficult to activate those regions uniformly through irradiation with laser light. When the first layer insulation film 29a is formed to a thickness of about 80 nm to increase the SiO₂ film thickness to 110 nm, the reflectivity moves from the point 123a to a point 123b along the reflectivity curve. Since the reflectivity indicated by the point 122 is substantially equal to the reflectivity indicated by the point 123b, the impurities can be substantially uniformly activated through irradiation with laser light.

Next, as shown in FIG. 8B, a SiO₂ film and a SiN film are formed in the order listed to thicknesses of about 60 nm and 380 nm respectively on the entire surface using a plasma CVD apparatus to form a second interlayer insulation film 31. A thermal process is then performed at 80° C. for two hours in a nitrogen atmosphere. An annealing process or hydrogen plasma process in a hydrogen atmosphere is used as a method of hydrogenating the second interlayer insulation film 31. The second interlayer insulation film 31 may be constituted only by a SiO₂ film that is formed with a sufficient thickness.

Next, as shown in FIG. 8C, a resist mask 32 for providing contact holes is formed, and dry etching is performed using a fluorine type gas to remove parts of the second interlayer insulation film 31, thereby providing contact holes for the source and drain regions 241, 243 and 245.

Next, as shown in FIG. 8D, after peeling off the resist mask 32, a Ti film, an Al film and another Ti film are formed in the order listed to thicknesses of about 100 nm, 200 nm and 100 nm respectively using a sputtering apparatus, the films serving as conductive thin films for forming source and drain electrodes. A resist is then applied and patterned, and the conductive thin films are etched with a chlorine type gas using the patterned resist layer as a mask to form source and drain electrodes 33. The resist mask is thereafter peeled off.

Next, a SiN film is formed to a thickness of about 400 nm as a third interlayer insulation film (not shown). A resist is then applied; the resist layer is patterned through exposure; and the SiN film is etched through dry etching with a fluorine type gas using the patterned resist layer as a mask to form contact holes. After peeling off the resist layer, an ITO film is formed to a thickness of about 70 nm using a sputtering apparatus. A resist is then applied and is exposed to form a patterned resist layer, and the ITO film is etched with an ITO etcher using the patterned resist layer as a mask. Thus, thin film transistor devices and a thin film transistor substrate and a liquid crystal display having the same in the present embodiment are formed.

In the n-channel TFT formed with LDDs manufactured according to the method of manufacture in the present embodiment, a buffer layer that is constituted by the underlying SiN film 22 and the SiO₂ film 23 is formed on the transparent insulated substrate 21. The polysilicon film 24 is formed on the buffer layer, and the source and drain regions 241, the LDD regions 247 and the channel region 248 are formed in the polysilicon film 24. The gate insulation film 26a is formed on the LDD regions 247 and the channel region 248 in the polysilicon film 24. The gate electrode 27a is formed on the gate insulation film 26a. The first interlayer insulation film 29a is formed on the gate insulation film 26a and the gate electrode 27a. The second interlayer insulation film 31 is formed on the first interlayer insulation film 29a and the source and drain regions 241 of the polysilicon film 24. The second interlayer insulation film 31 is provided with contact holes to form the source and drain electrodes 33 that are in contact with the source and drain regions 241 of the polysilicon film 24.

In the n-channel TFT formed with no LDD manufactured according to the method of manufacture in the present embodiment, a buffer layer that is constituted by the underlying SiN film 22 and the SiO₂ film 23 is formed on the transparent insulated substrate 21. The polysilicon film 24 is formed on the buffer layer, and the source and drain regions 243 and the channel region 244 are formed in the polysilicon film 24. The gate insulation film 26b and the gate electrode 27b are formed in the order listed on the channel region 244 of the polysilicon film 24. The second interlayer insulation film 31 is formed on the source and drain regions 243 and the gate electrode 27b. The second interlayer insulation film 31 is provided with contact holes to form the source and drain electrodes 33 that are in contact with the source and drain regions 243 of the polysilicon film 24.

In the p-channel TFT formed with no LDD manufactured according to the method of manufacture in the present embodiment, a buffer layer that is constituted by the underlying SiN film 22 and the SiO₂ film 23 is formed on the transparent insulated substrate 21. The polysilicon film 24 is formed on the buffer layer, and the source and drain regions 245 and the channel region 246 are formed in the polysilicon film 24. The gate insulation film 26c and the gate electrode 27c are formed on the channel region 246 in the polysilicon film 24. The second interlayer insulation film 31 is formed on the source and drain regions 245 and the gate electrode 27c. The second interlayer insulation film 31 is provided with contact holes to form the source and drain electrodes 33 that are in contact with the source and drain regions 245 of the polysilicon film 24.

As described above, according to the method of manufacturing TFT devices and a TFT substrate having the same in the present embodiment, the first interlayer insulation film 29 is formed after forming the gate electrode 27a; the impurity in a high density is implanted in the source and drain regions 241 of the polysilicon layer 24 using the gate electrode 27a, the gate insulation film 26a and the first interlayer insulation film 29a as masks after removing at least the first interlayer insulation film 29 and the gate insulation film 26 on the source and drain regions 241; the impurity in a low density is implanted through the gate insulation film 26a and the first interlayer insulation film 29a using the gate electrode 27a as a mask and is irradiated with laser light to be activated; and the second interlayer insulation film 31, the contact holes, and the source and drain electrodes 33 are then formed.

According to this method, the gate insulation film 26a and the first interlayer insulation film 29a are formed one over the other on the LDD regions 247. Since the multi-layer structure serves as a mask during the implantation of the impurity in a high density, it is possible to prevent the n-type impurity from being implanted in the LDD regions 247 in an unnecessarily great amount without adding a photolithographic process even when the gate insulation film 26a is thin. Transistors having LDD regions and transistors having no LDD region can be fabricated separately depending on the photoresist pattern used for etching the gate insulation films and the first interlayer insulation film. Further, as shown in FIG. 9, the degrees of reflection of laser light at the high density impurity-implanted regions that are source and drain regions 241 and the LDD regions can be made substantially equal by changing the thickness of the first interlayer insulation film in accordance with the thickness of the gate insulation film 26a, i.e., by adding only one step for forming the first interlayer insulation film. That is, those impurity regions can be simultaneously and sufficiently activated.

[Third Embodiment]

A description will now be made with reference to FIGS. 10A to 10D on thin film transistor devices, a method of manufacturing the same and a thin film transistor substrate having the same in a third embodiment of the invention. An LCD having a TFT substrate in the present embodiment will be not be described because it has the same configuration as that of the liquid crystal display 100 shown in FIG. 1 in the first embodiment. FIGS. 10A to 10D show a method of manufacturing polysilicon TFTs in which a peripheral circuit to be driven at a low voltage and a high speed has a CMOS configuration and in which a thin film transistor for driving a pixel is an n-channel TFT. In each of the figures, steps for manufacturing an n-channel TFT having LDDs are shown on the left side; steps for manufacturing an n-channel TFT having no LDD are shown in the middle; and steps for manufacturing a p-channel TFT having no LDD are shown on the right side. The n-channel TFT having LDDs is formed in a pixel matrix region 111, and the n-channel TFT and p-channel TFT having no LDD are formed in a gate driving circuit 113 and a drain driving circuit 112, for example.

First, as shown in FIG. 10A, an underlying SiN film 62 having a thickness of about 50 nm and a SiO₂ film 63 having a thickness of about 200 nm are formed in the order listed throughout a top surface of a transparent insulated substrate 61 made of glass using a plasma CVD apparatus. Subsequently, an amorphous silicon film of about 40 nm is formed throughout a top surface of the SiO₂ film 63. The amorphous silicon is then crystallized using an excimer laser to form a polysilicon film 64.

Next, a resist is applied and patterned, and dry etching is performed with a fluorine type gas using the patterned resist layer as a mask to remove parts of the polysilicon film 64, thereby forming polysilicon films in the form of islands.

After peeling off the resist mask, a SiO₂ film is formed on the polysilicon film in the form of islands to a thickness of about 30 nm using a plasma CVD apparatus to provide an insulation film 65. The insulation film 65 is formed with a thickness smaller than that of the insulation film 965 shown in FIGS. 15A to 15E according to the related art, for example. An Al—Nd film 66 to become gate electrodes is formed to a thickness of about 300 nm throughout a top surface of the insulation film 65 using a sputtering apparatus.

Next, a resist is applied on to the Al—Nd film 66 and is patterned to form resist masks in the form of gate electrodes. The Al—Nd film 66 is etched with an Al etcher using the resist masks to form gate electrodes 66a, 66b and 66c.

Next, after peeling off the resist masks, an n-type impurity such as P ions is implanted in a low density with an ion doping apparatus using the gate electrodes 66a, 66b and 66c as masks (first doping). The doping is performed at an acceleration energy of 40 keV and in a dose amount of 5×10¹³ cm⁻², for example. Thus, the n-type impurity is implanted in parts 641 of the polysilicon film to become LDD regions and source and drain regions in the case of the n-channel TFT to be formed with LDDs. The n-type impurity is also implanted in parts 643 and 645 to become source and drain regions in the polysilicon films for the n-channel TFT and p-channel TFT to be formed with no LDD. The n-type impurity is not implanted in parts 642, 644 and 646 to become channel regions because the gate electrodes 66a, 66b and 66c serve as masks. Since the doping is thus performed through the thin gate insulation film 65, the time required for doping can be short.

Next, as shown in FIG. 10B, a SiO₂ film is formed to a thickness of about 80 nm using a plasma CVD apparatus to provide a first layer insulation film 67.

Next, as shown in FIG. 10C, a resist is applied and is exposed to form a resist mask 68a such that it covers the parts to become the LDD regions and channel region of the polysilicon film for the n-channel TFT to be formed with LDDs and such that it covers the gate electrode 66a. The SiO₂ films serving as the first interlayer insulation film 67 and the gate insulation film 65 are then dry-etched using a fluorine type gas. This removes the first interlayer insulation film 67 and the gate insulation film 65 formed on the parts to become the source and drain regions of the n-channel TFT to be formed with LDDs, the first interlayer insulation film 67 and the gate insulation film 65 formed on the parts to become the source and drain regions of the n-channel TFT to be formed with no LDD, and the first interlayer insulation film 67 and the gate insulation film 65 formed on the parts to become the source and drain regions of the p-channel TFT to be formed with no LDD.

Next, after peeling off the resist mask 68a, P ions are implanted as an n-type impurity at an acceleration energy of 10 keV and in a dose amount of 1×10¹⁵ cm⁻², for example, with an ion doping apparatus using the first layer insulation film 67a, the gate electrodes 66b and 66c as masks, as shown in FIG. 10D. The doping will form source and drain regions 647 in the polysilicon film 64 for the n-channel TFT to be formed with LDDs and source and drain regions 643 in the polysilicon film 64 for the n-channel TFT to be formed with no LDD. The n-type impurity is also implanted in source and drain regions 645 in the polysilicon film 64 for the p-channel TFT to be formed with no LDD. Since the gate electrodes 66a, 66b and 66c serve as masks, the n-type impurity is not implanted in LDD regions and a part 642 to become a channel region in the polysilicon film 64 for the n-channel TFT to be formed with LDDs, a channel region 644 in the polysilicon film 64 for the n-channel TFT to be formed with no LDD, and a part 646 to become a channel region in the polysilicon film 64 for the p-channel TFT to be formed with no LDD.

Subsequent steps will be briefly described because they are similar to those shown in FIG. 7D and later in the second embodiment. A resist is applied and patterned to form a resist layer that is patterned to cover the n-channel TFT to be formed with LDDs and the n-channel TFT to be formed with no LDD. For example, a p-type impurity such as B ions is implanted at an acceleration energy of 10 keV and in a dose amount of 2×10¹⁵ cm⁻² with an ion doping apparatus using the patterned resist layer and the gate electrode 66c as masks. Thus, source and drain regions 645 are formed in the polysilicon film 64 for the p-channel TFT to be formed with no LDD. Since the source and drain regions 645 in the polysilicon film 64 for the p-channel TFT to be formed with no LDD have already been doped with the n-type impurity, they are doped with a greater amount of the p-type impurity to invert the conductivity type.

The resist mask is then fully ashed. The impurity is then activated by irradiating it with laser light from an excimer laser apparatus. SiO₂ films, i.e., a gate insulation film 65a of about 30 nm and a first interlayer insulation film 67a of about 80 nm are formed on LDD regions 648 of the n-channel TFT to be formed with LDDs. On the contrary, no SiO₂ film exists on the source and drain regions 647. Thus, the degrees of reflection of laser light at those regions can be substantially equal to each other as already described with reference to FIG. 9.

Next, a SiO₂ film and a SiN film are formed in the order listed to thicknesses of about 60 nm and 380 nm respectively using a plasma CVD apparatus to form a second interlayer insulation film. It is subjected to a thermal process at 380° C. for two hours in a nitrogen atmosphere. It is also hydrogenated through an annealing process.

A resist is then applied, and exposure is performed to pattern the resist layer. Dry etching is performed with a fluorine type gas using the resist layer as a mask to remove parts of the second interlayer insulation film, thereby forming contact holes for the source and drain regions 647, 643 and 645.

Next, after peeling off the resist mask 32, a Ti film, an Al film and another Ti film as conductive thin films are formed in the order listed to thicknesses of about 100 nm, 200 nm and 100 nm respectively using a sputtering apparatus. A resist is then applied and patterned, and the conductive thin films are etched with a chlorine type gas using the patterned resist layer as a mask to form source and drain electrodes 33. The resist mask is thereafter peeled off.

Next, a SiN film is formed to a thickness of about 400 nm as a third interlayer insulation film. A resist is then applied and patterned, and the SiN film is etched through dry etching with a fluorine type gas using the patterned resist layer as a mask to form contact holes. Further, an ITO film is formed to a thickness of about 70 nm using a sputtering apparatus. A resist is then applied and patterned, and the ITO film is etched with an ITO etcher using the patterned resist layer as a mask. Thus, thin film transistor devices and a thin film transistor substrate and a liquid crystal display having the same in the present embodiment are formed.

According to the method of manufacturing a TFT substrate in the present embodiment, after forming the gate electrodes, the impurity in a low density is implanted through the gate electrodes to form the first interlayer insulation film; the n-type impurity in a high density is implanted in the source and drain regions in the polysilicon layer using the gate electrodes, the gate insulation film and the first interlayer insulation film as masks after removing at least the first interlayer insulation film and the gate insulation film on the source and drain regions; the impurity is activated by irradiating it with laser light to form the second interlayer insulation film; and the contact holes and the source and drain electrodes are then formed. Like the first embodiment, the method of manufacture in the present embodiment makes it possible to control the amount of an impurity implanted in LDD regions without adding a photolithographic process even when a gate insulation film is thin and to adjust the reflectivity of source and drain regions and LDD regions using an interlayer insulation film. That is, those impurity regions can be simultaneously and sufficiently activated.

While an LCD has been used as an example of a display in the above-described embodiments of the invention, the invention is not limited to the same. For example, as well as LCD, the invention may be applied to flat panel displays such as thin film organic EL displays that are gathering expectations as displays to replace CRTs (cathode ray tubes). The main stream of such flat panel displays is active matrix type displays in which a TFT is provided in each pixel as a switching element to achieve high speed response and low power consumption. In an active matrix flat panel display, there is a need for fabricating a TFT at each of a multiplicity of pixels arranged in the form of a matrix on a substrate, even in which case the methods of manufacture described in the above embodiments can be used.

As described above, the invention makes it possible to form LDD regions easily in the optimum manner even when the gate insulation film is thin. Further, an implanted impurity can be easily in the optimum manner even when the gate insulation film is thin.

What is claimed is:

1. A method of manufacturing a thin film transistor device, comprising the steps of:
forming a semiconductor layer having a predetermined configuration on a substrate;
forming a first insulation film on the semiconductor layer;
forming a gate electrode of a thin film transistor of a first conductivity type on the first insulation film;
forming source and drain regions and low density impurity regions by implanting an impurity of the first conductivity type in the semiconductor layer using the gate electrode as a mask;
forming a mask layer on the low density impurity regions;
forming a gate insulation film by patterning the first insulation film using the mask layer and implanting the impurity of the first conductivity type in the source and drain regions using the mask layer continuously; and
forming a second insulation film having a predetermined thickness on the source and drain regions and the low density impurity regions after removing the mask layer and irradiating the same with laser light to activate the impurity in the source and drain regions and the low density impurity regions.

2. A method of manufacturing a thin film transistor device according to claim 1, further comprising the steps of:
forming a gate electrode of a thin film transistor of a second conductivity type on the first insulation film at the same time when the gate electrode of the transistor of the first conductivity type is formed;
forming a gate insulation film of the thin film transistor of the second conductivity type at the same time when the gate insulation film of the transistor of the first conductivity type is formed;
forming a second mask layer on the thin film transistor of the first conductivity type after removing the mask layer and before the irradiation with laser light; and
implanting an impurity of the second conductivity type in source and drain regions of the thin film transistor of the second conductivity type using the second mask layer.

3. A method of manufacturing a thin film transistor device, comprising the steps of:
forming a semiconductor layer having a predetermined configuration on a substrate;
forming a first insulation film on the semiconductor layer;
forming a gate electrode of a thin film transistor of a first conductivity type on the first insulation film;
forming a second insulation film having a predetermined thickness and thereafter forming a gate insulation film and a mask layer having the predetermined thickness on the semiconductor layer under the gate electrode and in the vicinity thereof by patterning the first and second insulation films;
forming source and drain regions by implanting an impurity of the first conductivity type in the semiconductor layer using the gate electrode, the gate insulation film, and the mask layer as a masks;
forming low density impurity regions in the vicinity of the gate electrode by implanting the impurity of the first conductivity type in the semiconductor layer under different conditions for impurity implantation using the gate electrode as a mask; and
activating the impurity in the source and drain regions and the low density impurity regions by irradiating with laser light.

4. A method of manufacturing a thin film transistor device according to claim 3, further comprising the steps of:
forming a gate electrode of a thin film transistor of a second conductivity type on the first insulation film at the same time when the gate electrode of the transistor of the first conductivity type is formed;
forming a gate insulation film of the thin film transistor of the second conductivity type at the same time when the gate insulation film of the transistor of the first conductivity type is formed;
forming a second mask layer on the thin film transistor of the first conductivity type after forming the low density impurity regions and before the irradiation with laser light; and
implanting an impurity of the second conductivity type in source and drain regions of the thin film transistor of the second conductivity type using the second mask layer.

5. A method of manufacturing a thin film transistor device, comprising the steps of:
forming a semiconductor layer having a predetermined configuration on a substrate;
forming a first insulation film on the semiconductor layer;
forming a gate electrode of a thin film transistor of a first conductivity type on the first insulation film;
forming source and drain regions and low density impurity regions by implanting an impurity of the first conductivity type in the semiconductor layer using the gate electrode as a mask;
forming a second insulation film having a predetermined thickness and thereafter forming a gate insulation film and a mask layer having the predetermined thickness on the low density impurity regions under the gate electrode and in the vicinity thereof by patterning the first and second insulation films;
forming source and drain regions by implanting the impurity of the first conductivity type in the semiconductor layer under different conditions for impurity implantation using the gate electrode, the gate insulation film, and the mask layer as masks; and
activating the impurity in the source and drain regions and the low density impurity regions by irradiating with laser light.

6. A method of manufacturing a thin film transistor device according to claim 5, further comprising the steps of:
forming a gate electrode of a thin film transistor of a second conductivity type on the first insulation film at the same time when the gate electrode of the transistor of the first conductivity type is formed;
forming a gate insulation film of the thin film transistor of the second conductivity type at the same time when the gate insulation film of the transistor of the first conductivity type is formed;
forming a second mask layer on the thin film transistor of the first conductivity type after forming the source and drain regions and before the irradiation with laser light; and
implanting an impurity of the second conductivity type in source and drain regions of the thin film transistor of the second conductivity type using the second mask layer.

7. A method of manufacturing a thin film transistor device according to claim 1, further comprising the steps of:
forming a third insulation film on the second insulation film;
forming contact holes by providing openings in each of the second and third insulation films on the source and drain regions; and
forming source and drain electrodes that are connected to the source and drain regions respectively through the contact holes.

8. A method of manufacturing a thin film transistor device according to claim 1, wherein the thickness of the second insulation film is determined such that the degrees of reflection of the laser light at the low density impurity regions and the source and drain regions of the thin film transistor of the first conductivity type are substantially equal to each other.

9. A method of manufacturing a thin film transistor device according to claim 3, wherein the thickness of the second insulation film is determined such that the degrees of reflection of the laser light at the low density impurity regions and the source and drain regions of the thin film transistor of the first conductivity type are substantially equal to each other.

10. A method of manufacturing a thin film transistor device according to claim 5, wherein the thickness of the second insulation film is determined such that the degrees of reflection of the laser light at the low density impurity regions and the source and drain regions of the thin film transistor of the first conductivity type are substantially equal to each other.

11. A method of manufacturing a thin film transistor device according to claim 8, wherein the thickness of the second insulation film is determined based on the thickness of the first insulation film.

12. A method of manufacturing a thin film transistor device according to claim 9, wherein the thickness of the second insulation film is determined based on the thickness of the first insulation film.

13. A method of manufacturing a thin film transistor device according to claim 10, wherein the thickness of the second insulation film is determined based on the thickness of the first insulation film.

14. A thin film transistor device comprising:
a semiconductor layer having a predetermined configuration formed on a substrate;
a first insulation film formed on the semiconductor layer;
a gate electrode of a thin film transistor of a first conductivity type formed on the first insulation film;
source and drain regions and low density impurity regions formed by implanting an impurity of the first conductivity type in the semiconductor layer; and
a second insulation film having a predetermined thickness formed on the source and drain regions and the low density impurity regions.

15. A thin film transistor device comprising:
a semiconductor layer having a predetermined configuration formed on a substrate;
a first insulation film formed on the semiconductor layer;
a gate electrode of a thin film transistor of a first conductivity type formed on the first insulation film;
a gate insulation film formed on the semiconductor layer under the gate electrode and in the vicinity of the same;
a second insulation layer serving as a mask layer for implanting an impurity of the first conductivity type in the semiconductor layer;
source and drain regions formed by implanting an impurity of the first conductivity type in the semiconductor layer using the gate electrode, the gate insulation film, and the second insulation film as masks; and
low density impurity regions formed in the vicinity of the gate electrode by implanting the impurity of the first conductivity type in the semiconductor layer under different conditions for impurity implantation using the gate electrode as a mask.

16. A thin film transistor device comprising:
a semiconductor layer having a predetermined configuration formed on a substrate;
a first insulation film formed on the semiconductor layer;
a gate electrode of a thin film transistor of a first conductivity type formed on the first insulation film;
low density impurity regions formed by implanting an impurity of the first conductivity type in the semiconductor layer;
a gate insulation film formed on the semiconductor layer under the gate electrode and in the vicinity of the same;
a second insulation film formed on the low density impurity regions as a mask layer for implanting the impurity of the first conductivity type in the semiconductor layer; and
source and drain regions formed by implanting the impurity of the first conductivity type in the semiconductor layer using the gate electrode, the gate insulation film, and the second insulation film as masks.

17. A thin film transistor device according to claim 14, further comprising a thin film transistor of a second conductivity type.

18. A thin film transistor device according to claim 14, comprising:
a third insulation film formed on the second insulation film;
contact holes formed by providing openings in each of the second and third insulation films on the source and drain regions; and
source and drain electrodes that are connected to the source and drain regions respectively through the contact holes.

19. A thin film transistor device according to claim 14, wherein the second insulation film has a thickness such that the degrees of reflection of the laser light at the low density impurity regions and the source and drain regions of the thin film transistor of the first conductivity type are substantially equal to each other.

20. A thin film transistor device according to claim 15, wherein the second insulation film has a thickness such that the degrees of reflection of the laser light at the low density impurity regions and the source and drain regions of the thin film transistor of the first conductivity type are substantially equal to each other.

21. A thin film transistor device according to claim 16, wherein the second insulation film has a thickness such that the degrees of reflection of the laser light at the low density impurity regions and the source and drain regions of the thin film transistor of the first conductivity type are substantially equal to each other.

22. A thin film transistor device according to claim 19, wherein the thickness of the second insulation film is determined based on the thickness of the first insulation film.

23. A thin film transistor device according to claim 20, wherein the thickness of the second insulation film is determined based on the thickness of the first insulation film.

24. A thin film transistor device according to claim 21, wherein the thickness of the second insulation film is determined based on the thickness of the first insulation film.

25. A thin film transistor substrate comprising the first thin film transistor devices connected to pixel electrodes arranged in the form of a matrix in a display area and second thin film transistor devices formed at a peripheral circuit outside the display area, the first and second transistor devices including a thin film transistor device according to claim 14.

26. A display apparatus comprising a substrate having a thin film transistor device to serve as a switching element, wherein the substrate is a thin film transistor substrate according to claim 25.
